(19) United States
(12) Patent Application Publication
(10) Pub. No.: US 2025/0140629 A1
(43) Pub. Date: May 1, 2025

(54) SEMICONDUCTOR DEVICE

(71) Applicant: FUJI ELECTRIC CO., LTD., Kawasaki-shi (JP)

(72) Inventor: Shingo HAYASHI, Matsumoto-city (JP)

(73) Assignee: FUJI ELECTRIC CO., LTD., Kawasaki-shi (JP)

(21) Appl. No.: 18/816,716

(22) Filed: Aug. 27, 2024

(30) Foreign Application Priority Data
Oct. 26, 2023 (JP) 2023-184027

(51) Int. Cl. H01L 23/31; H01L 23/29; H01L 29/06; H01L 29/16; H01L 29/78

(52) U.S. Cl. CPC H01L 23/3192; H01L 23/293; H01L 23/3171; H10D 30/665; H10D 30/668; H10D 62/107; H10D 62/109; H10D 62/8325

(57) ABSTRACT

In a semiconductor device having an active region and a termination region surrounding a periphery of an active region, the termination region includes a semiconductor substrate of a first conductivity type; a first semiconductor region of the first conductivity type, provided on a surface of the semiconductor substrate, the first semiconductor region having a thickness “d”; an insulating film provided on a surface of the first semiconductor region; and a polyimide film provided on a surface of the insulating film, the polyimide film being provided at least a distance of 0.66 d from an end of the semiconductor device.

### CROSS REFERENCE TO RELATED APPLICATIONS

This application is based upon and claims the benefit of priority of the prior Japanese Patent Application No. 2023-184027, filed on Oct. 26, 2023, the entire contents of which are incorporated herein by reference.

### BACKGROUND OF THE INVENTION

### 1. Field of the Invention

Embodiments of the disclosure relate to a semiconductor device.

### 2. Description of the Related Art

A silicon carbide (SiC) semiconductor device has been proposed in which an end insulating film and a passivation film are provided on a SiC epitaxial layer, the passivation film being apart from an end of a dicing region (for example, refer to Japanese Laid-Open Patent Publication No. 2018-93209).

### SUMMARY OF THE INVENTION

According to an embodiment to of the present disclosure, a semiconductor device has an active region and a termination region surrounding a periphery of the active region, and in the termination region, the semiconductor device includes: a semiconductor substrate of a first conductivity type; a first semiconductor region of the first conductivity type, provided on a surface of the semiconductor substrate, the first semiconductor region having a thickness “d”; an insulating film provided on a surface of the first semiconductor region; and a polyimide film selectively provided on a surface of the insulating film. The polyimide film is provided at least a distance of 0.66 d from an outer periphery end of the semiconductor device.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view depicting an edge termination region of a semiconductor device according to an embodiment.

FIG. 2 is a graph depicting a relationship between dicing surface angle of the semiconductor device according to the embodiment and a distance from an end of the semiconductor device to a polyimide film.

FIG. 3 is a cross-sectional view depicting a structure of the edge termination region of the semiconductor device according to the embodiment.

FIG. 4 is a cross-sectional view depicting a structure of an active region of the semiconductor device according to the embodiment.

FIG. 5 is a cross-sectional view depicting an edge termination region of a conventional semiconductor device.

### DETAILED DESCRIPTION OF THE INVENTION

First, problems associated with the conventional technique are discussed. A flow of reflux current to an intrinsic diode generates blue light and when a polyimide covering the semiconductor device absorbs the blue light emitted from an end of the semiconductor device, a composition (structure) of the polyimide changes and, for example, adhesion degrades, whereby reliability of the semiconductor device may decrease.

A semiconductor device according to the present disclosure and solving the described problems has the following features. The semiconductor device has an active region and a termination region surrounding a periphery of the active region. The termination region includes a semiconductor substrate of a first conductivity type; a first semiconductor region of the first conductivity type, provided on a surface of the semiconductor substrate, the first semiconductor region having a thickness “d”; an insulating film provided on a surface of the first semiconductor region; and a polyimide film selectively provided on a surface of the insulating film. The polyimide film is provided at least a distance of 0.66 d from an end (outer periphery end) of the semiconductor device.

According to the disclosure above, even when blue light is transmitted through the interlayer insulating film and emitted from the surface of the semiconductor device, the blue light is not absorbed by the polyimide film. Thus, decreases in the reliability of the semiconductor device may be prevented without changes in the composition (structure) of the polyimide film due to the blue light and without degradation of adhesion between the polyimide film and the interlayer insulating film.

Further, in the semiconductor device according to the present disclosure, in the disclosure above, the semiconductor device has a side surface that is inclined inward at θ degrees from vertical, and the polyimide film is provided at least a distance of 0.66 d+d tan θ from the end of the semiconductor device.

Further, in the semiconductor device according to the present disclosure, in the disclosure above, the side surface of the semiconductor device is inclined inward at θ degrees from vertical, the semiconductor substrate has a thickness “D”, and the polyimide film is provided at least a distance of 0.66 d+D tan θ from the end of the semiconductor substrate.

According to the disclosure above, even in an instance in which the side surface of the semiconductor device is θ degrees from vertical, the blue light is not absorbed by the polyimide film.

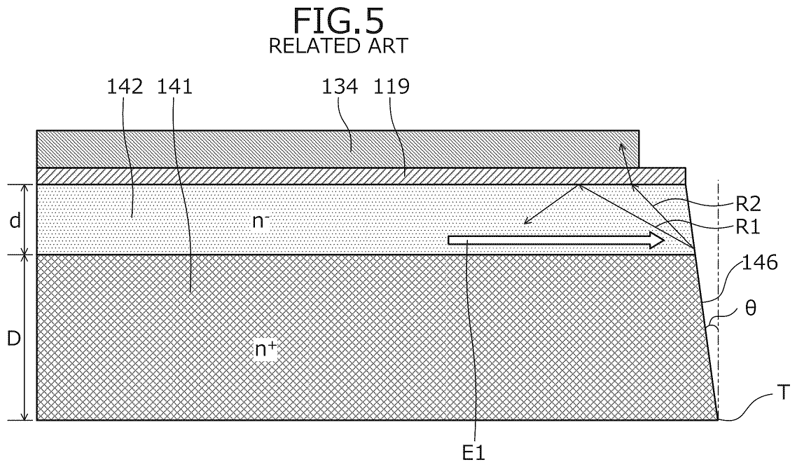

Findings underlying the present disclosure are discussed. Here, problems associated with a conventional semiconductor device are discussed. FIG. 5 is a cross-sectional view depicting an edge termination region of a conventional semiconductor device. The edge termination region is a region that surrounds a periphery of an active region through which current flows during an on-state; a voltage withstanding structure is provided in the edge termination region. In FIG. 5, the voltage withstanding structure is not depicted. In the edge termination region, an n⁻-type silicon carbide layer 142 is provided on an n⁺-type starting substrate 141 while an interlayer insulating film 119 and a polyimide film 134 are provided on the n⁻-type silicon carbide layer 142.

As depicted in FIG. 5, the interlayer insulating film 119 is provided on the n⁻-type silicon carbide layer 142, in an entire area of the surface of the n⁻-type silicon carbide layer 142. The surface of the semiconductor device is protected by the polyimide film 134, the polyimide film 134 being formed up to a vicinity of a side surface 146 of the semiconductor device. In an instance in which the semiconductor device is a SiC metal oxide semiconductor field effect transistor (SiC-MOSFET), the SiC-MOSFET has an intrinsic diode. When a reflux current flows through the intrinsic diode, high-energy blue light corresponding to a band gap energy of SiC is generated. In an instance in which the semiconductor device is a SiC insulated gate bipolar transistor (SiC-IGBT), the semiconductor device operates bipolarly when turning on normally and thus, blue light is generated and the amount of light generated is greater than the amount generated by a SiC-MOSFET.

The surface of the semiconductor device is covered by a metal electrode such as a source electrode and thus, the blue light is reflected by the metal electrode and spreads in the semiconductor device, in a horizontal direction E1 rather than being emitted directly from the surface. The blue light spreading in the horizontal direction may be emitted from the side surface 146 of the semiconductor device or may be reflected by the side surface 146 of the semiconductor device and thereby, emitted from the surface nearby.

In an instance in which the blue light spreading in the semiconductor device in the horizontal direction E1 is reflected by the side surface 146 of the semiconductor device, when an angle of incidence of the blue light at an interface between the interlayer insulating film 119 and the n⁻-type silicon carbide layer 142 is small such as with a path R2, the blue light is transmitted through the interlayer insulating film 119 and when the angle of incidence of the blue light is large such as with a path R1, the blue light is reflected by the interlayer insulating film 119. When the blue light is transmitted through the interlayer insulating film 119 such as with the path R2, in the conventional semiconductor device, the polyimide film 134 is formed up to a vicinity of the side surface 146 of the semiconductor device and thus, the blue light is absorbed by the polyimide film 134. Problems arises in that a composition (structure) of the polyimide film 134 that has absorbed the blue light changes due to the energy of the blue light, whereby characteristics such as adhesion between the interlayer insulating film 119 and the polyimide film 134 degrade, and reliability of the semiconductor device decreases.

Embodiments of a semiconductor device according to the present disclosure are described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

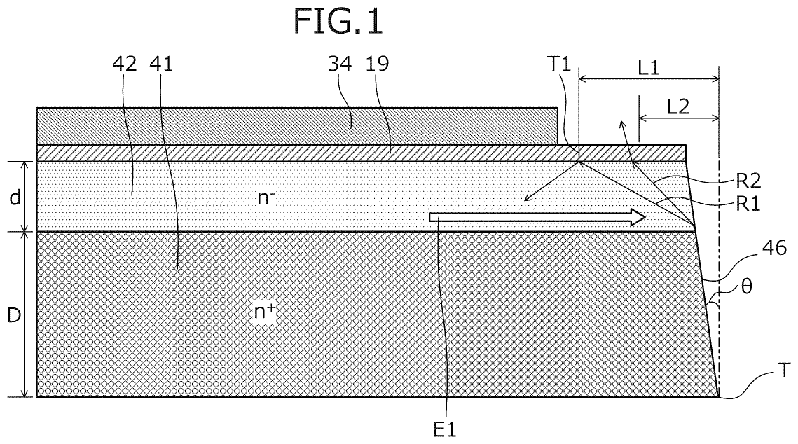

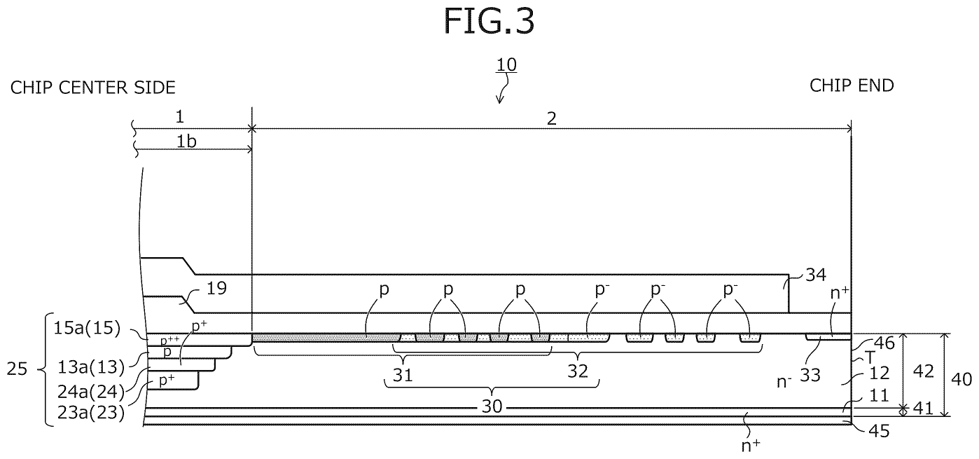

A semiconductor device according to an embodiment solving the problems above is described. A structure of a silicon carbide semiconductor device is described as the semiconductor device according to the embodiment. FIG. 1 is a cross-sectional view depicting an edge termination region of the semiconductor device according to the embodiment. FIG. 1 depicts a general structure of the edge termination region (refer to FIG. 3 for a detailed depiction of the structure).

As depicted in FIG. 1, in the edge termination region of the semiconductor device according to the embodiment, an n⁻-type silicon carbide layer 42 is provided on an n⁺-type starting substrate 41 while an interlayer insulating film 19 and a polyimide film 34 are provided on the n⁻-type silicon carbide layer 42. The n⁺-type starting substrate 41 constitutes a drain region and the n⁻-type silicon carbide layer 42 constitutes a drift layer and is formed by epitaxial growth. The interlayer insulating film 19, for example, is an oxide film constituted by a SiO₂ film. The interlayer insulating film 19 is provided on the n⁻-type silicon carbide layer 42, in an entire area of the surface of the n⁻-type silicon carbide layer 42. The surface of the semiconductor device is protected by the polyimide film 34, which is formed away from a side surface 46 of the semiconductor device.

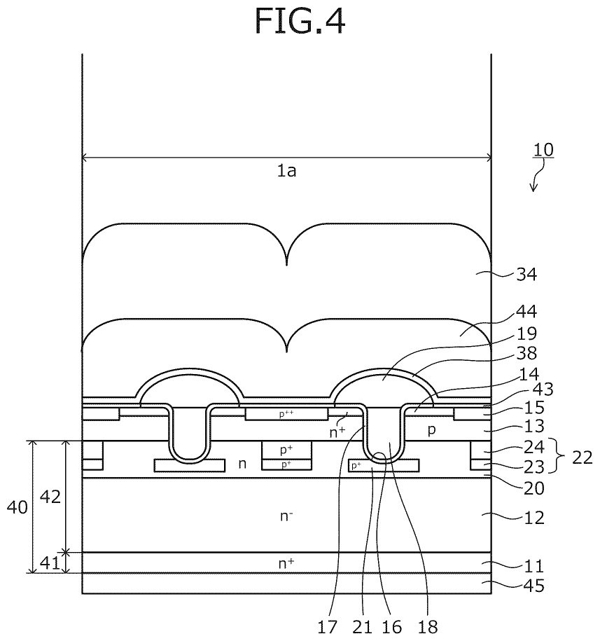

As described above, when the intrinsic diode of the SiC-MOSFET conducts or when the SiC-IGBT turns on, high-energy blue light (includes ultraviolet light having a shorter wavelength than a wavelength of blue light) is generated. For example, in an instance of a later-described MOSFET having a trench gate structure depicted in FIG. 4, holes injected from p⁺-type regions 21, which protect against electric field applied to the trenches, reach the n⁺-type starting substrate 41 and recombine with electrons, thereby generating blue light. While the blue light is mainly emitted outside the device from the side surface 46 of the semiconductor device, a portion is reflected and travels toward the surface. Whether this reflected blue light is reflected by the surface of the semiconductor device or transmitted through and emitted outside is determined by refractive indices of the n⁻-type silicon carbide layer 42 and the interlayer insulating film 19 and the angle of incidence of the blue light.

In an instance in which the blue light that spreads in the semiconductor device in the horizontal direction E1 is reflected by the side surface 46 of the semiconductor device, when the angle of incidence of the blue light at an interface between the interlayer insulating film 19 and the n⁻-type silicon carbide layer 42 is small such as with the path R2, the blue light is transmitted through the interlayer insulating film 19 and when the angle of incidence of the blue light is large such as with the path R1, the blue light is completely reflected by the interlayer insulating film 19. Whether the blue light is transmitted or completely reflected is dependent on a distance from the side surface 46 of the semiconductor device and in an area from a boundary T1 to the side surface 46, the blue light is transmitted whereas in an area from the boundary T1 and extending in a direction opposite to the side surface 46, the blue light is completely reflected. Thus, in the embodiment, the polyimide film 34 is formed to be apart from an end T of the semiconductor device by a distance to the boundary T1 from the end T and a position of the polyimide film 34 near the end T of the semiconductor device is limited to a region outside the area from where the blue light is emitted to outside the semiconductor device. The end T of the semiconductor device is a starting point of the side surface 46 of the semiconductor device and an outermost position in the semiconductor device.

The angle of incidence of the blue light at the interface between the interlayer insulating film 19 and the n⁻-type silicon carbide layer 42, decreases with increasing depth of a position of luminescence and transmission of the blue light from the surface is facilitated. The blue light is generated in an area extending in the n⁻-type silicon carbide layer 42, from an interface between the n⁻-type silicon carbide layer 42 and the n⁺-type starting substrate 41 and thus, a distance L1 of the boundary T1 from the end T of the semiconductor device is dependent on a thickness d of the n⁻-type silicon carbide layer 42, which constitutes the drift layer. The distance L1 is about 0.66 d or more and thus, blue light transmitted through the interlayer insulating film 19 may be prevented from being absorbed by the polyimide film 34. The thicker the n⁻-type silicon carbide layer 42 is provided, the greater is the need for the polyimide film 34 to be apart from the end T of the semiconductor device.

Thus, in the semiconductor device according to the embodiment, the polyimide film 34 is apart from the end T of the semiconductor device by at least 0.66 d. As a result, blue light transmitted through the interlayer insulating film 19 such as that on the path R1 is not absorbed by the polyimide film 34 even when the blue light is not emitted from the surface of the semiconductor device. Further, in a region in which the polyimide film 34 is provided, blue light such as that on the path R2 is completely reflected and not emitted from the surface of the semiconductor device. Thus, decreases in the reliability of the semiconductor device may be prevented without changes in the composition (structure) of the polyimide film 34 due to the blue light and without degradation of adhesion between the polyimide film 34 and the interlayer insulating film 19 or the like.

Further, in an instance in which the side surface 46 of the semiconductor device is vertical, the entire surface is uniform with the end T of the semiconductor device, however, due to dicing, the side surface 46 of the semiconductor device may not be vertical. In this instance, the side surface 46 of the semiconductor device is inclined toward the active region and thus, the polyimide film 34 has to be farther apart from the end T. The angle of incidence of the blue light decreases with increasing depth of the position of luminescence and thus, it is necessary to prevent the blue light reflected near the interface between the n⁺-type starting substrate 41 and the n⁻-type silicon carbide layer 42 from being absorbed by the polyimide film 34.

In an instance in which the side surface 46 of the semiconductor device is inclined 0 degrees from vertical by dicing, a portion of the side surface 46 at an interface between the interlayer insulating film 19 and the n⁻-type silicon carbide layer 42 is closer to the polyimide film 34 by d tan θ than is a portion of the side surface 46 at the interface between the n⁺-type starting substrate 41 and the n⁻-type silicon carbide layer 42. Further, assuming a thickness of the n⁺-type starting substrate 41 to be “D”, at the interface between the n⁺-type starting substrate 41 and the n⁻-type silicon carbide layer 42, the inclined side surface 46 of the semiconductor device is closer to the polyimide film 34 by D tan θ as compared to an instance without incline of the side surface 46. Thus, when the side surface 46 of the semiconductor device is θ degrees from vertical, preferably, the polyimide film 34 may be at least 0.66 d+d tan θ from the end T of the semiconductor device and more preferably, may be 0.66 d+D tan θ or more from the end T of the semiconductor device. As a result, even when the side surface 46 of the semiconductor device is θ degrees from vertical, blue light is not absorbed by the polyimide film 34. When the semiconductor device includes a back structure such as in an IGBT, the thickness D of the n⁺-type starting substrate 41 is a thickness including the back structure.

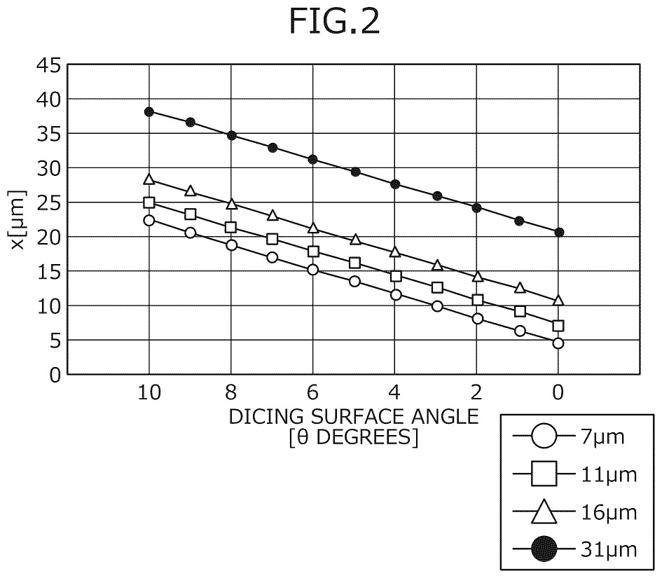

FIG. 2 is a graph depicting a relationship between dicing surface angle of the semiconductor device according to the embodiment and a distance of 0.66 d+D tan θ from the end of the semiconductor device to the polyimide film. In FIG. 2, a horizontal axis indicates an angle θ (dicing surface angle) that the side surface 46 of the semiconductor device deviates from vertical in units of degrees. A vertical axis indicates a distance x that the polyimide film 34 is apart from the end T of the semiconductor device in units of μm. FIG. 2 depicts instances in which the thickness d of the n⁻-type silicon carbide layer 42 is 7 μm, 11 μm, 16 μm, and 31 μm, respectively, and an instance in which the thickness D of the n⁺-type starting substrate 41 is, for example, 100 μm.

Next, a structure of the semiconductor device according to the embodiment is described. Here, an instance in which the semiconductor device is a SiC-MOSFET is described as an example. FIG. 3 is a cross-sectional view depicting the structure of the edge termination region of the semiconductor device according to the embodiment. A silicon carbide semiconductor device 10 depicted in FIG. 3 is a vertical MOSFET with a trench gate structure; the silicon carbide semiconductor device 10 has a semiconductor substrate (semiconductor chip) 40 containing silicon carbide (SiC) and a voltage withstanding structure 30 provided in an edge termination region 2 of the semiconductor substrate 40.

In the semiconductor substrate 40, multiple unit cells (functional units of a device) each having a same MOSFET structure (device structure) are provided adjacent to one another in a center portion 1a (refer to FIG. 4) of an active region 1. The active region 1 is a region through which a main current (drift current) flows when the MOSFET is on. The active region 1 has a substantially rectangular shape in a plan view of the device and is disposed in substantially a center (chip center) of the semiconductor substrate 40. The active region 1 is a center portion (chip center), in a plan view of the device, extending from an outer side (side facing an end (chip end) of the semiconductor substrate 40) of a later-described p⁺⁺-type extended contact portion 15a, in a direction opposite to a direction to the side surface 46.

The edge termination region 2 is a region between the active region 1 and the chip end; the edge termination region 2 surrounds a periphery of the active region 1 in substantially a rectangular shape in a plan view of the device. In the edge termination region 2, the voltage withstanding structure 30 is provided. The voltage withstanding structure 30 has a function of mitigating electric field near a boundary between the active region 1 and the edge termination region 2 and sustaining a breakdown voltage. A configuration of the voltage withstanding structure 30 is described hereinafter. The breakdown voltage is a voltage limit at which a drain-source voltage does not further increase even when a drain-source current increases due to avalanche breakdown by pn junctions.

In the semiconductor substrate 40, an n⁻-type drift region (first semiconductor region) 12 constituting the n⁻-type silicon carbide layer 42 is formed by epitaxy on a front surface of the n⁺-type starting substrate 41 containing silicon carbide. The semiconductor substrate 40 has, as a front surface (first main surface), a main surface constituted by a surface of the n⁻-type silicon carbide layer 42, the semiconductor substrate 40 further has, as back surface (second main surface), a main surface constituted by a surface of the n⁺-type starting substrate 41.

The n⁺-type starting substrate 41 constitutes an n⁺-type drain region 11. The semiconductor substrate 40 is formed by forming the n⁻-type silicon carbide layer 42 (constitutes the n⁻-type drift region 12) in multiple stages sequentially by epitaxy when portions of the active region 1 are formed. The n⁻-type drift region 12 is a portion of the n⁻-type silicon carbide layer 42 left free of diffused regions formed by ion implantation, the n⁻-type drift region 12 having the doping concentration at the time of formation of the n⁻-type silicon carbide layer 42 by epitaxy. The n⁻-type drift region 12 is in contact with the n⁺-type starting substrate 41 and is provided spanning the active region 1 to the chip end.

An outer peripheral portion 1b of the active region 1 surrounds a periphery of the center portion 1a of the active region 1, in a substantially rectangular shape in a plan view of the device. In a longitudinal direction of later-described trenches 16, the outer peripheral portion 1b of the active region 1 is a portion from an outermost end of later-described n⁺-type source regions 14, to the boundary between the active region 1 and the edge termination region 2. In a lateral direction of the trenches 16, the outer peripheral portion 1b of the active region 1 is a portion from each outermost (closest to the chip end) sidewall of outermost ones of the trenches 16, to the boundary between the active region 1 and the edge termination region 2. The outer peripheral portion 1b of the active region 1 is free of the MOSFET unit cells.

In the outer peripheral portion 1b of the active region 1, in an entire area between the front surface of the semiconductor substrate 40 and the n⁻-type drift region 12, the p⁺⁺-type extended contact portion 15a, a p-type extended base portion 13a, a lower portion 23a of a p⁺-type extended portion, and an upper portion 24a of the p⁺-type extended portion are provided sequentially and adjacent to one another, in stated order, in a depth direction from the front surface of the semiconductor substrate 40. These regions are, respectively, extended portions of an outermost one (closest to the chip end) of p⁺⁺-type contact regions 15, a p-type base region 13, a lower portion 23 of an outermost one (closest to a chip end) of p⁺-type regions, an upper portion 24 of the outermost one of the p⁺-type regions of the center portion 1a of the later-described active region 1, the extended portions extending into the outer peripheral portion 1b of the active region. In the outer peripheral portion 1b of the active region 1, these regions (the extended portions) configure a single p-type outer peripheral region 25, in an entire area between the front surface of the semiconductor substrate 40 and the n⁻-type drift region 12.

The extended portions configuring the p-type outer peripheral region 25 of the outer peripheral portion 1b of the active region 1 concentrically surround the periphery of the center portion 1a of the active region 1 in a plan view of the device. The p-type outer peripheral region 25 is a region for leading hole current out to a later-described source electrode 44, the hole current being generated by the n⁻-type drift region 12 of the edge termination region 2 when the MOSFET (the silicon carbide semiconductor device 10) is off and flowing in a direction to the active region 1; the p-type outer peripheral region 25 is electrically connected to the source electrode 44. When the MOSFET is off, the hole current generated by the n⁻-type drift region 12 of the edge termination region 2 is lead out to the source electrode 44 via the p-type outer peripheral region 25, whereby concentration of the hole current during avalanche breakdown in the edge termination region 2 is suppressed.

The voltage withstanding structure 30 of the edge termination region 2, for example, is a spatial modulation JTE structure having a JTE structure as a spatial modulating structure and is configured by multiple p-type regions 31 and multiple p⁻-type regions 32 selectively provided between the front surface of the semiconductor substrate 40 and the n⁻-type drift region 12. The p-type regions 31 and the p-type regions 32 are diffused regions formed by ion implantation in surface regions of the n⁻-type silicon carbide layer 42.

The p-type regions 31 are disposed apart from one another, concentrically surrounding the periphery of the active region 1, in a plan view of the device. The p-type regions 31 are disposed in descending order of width (width in a direction of a normal from an inner side to an outer side) in a direction from the chip center to the chip end, and an interval between any one of the p-type regions 31 and an adjacent one of the p-type regions closer to the chip end is wider than an interval between said any one of the p-type regions 31 and an adjacent one of the p-type regions 31 closer to the chip center. An innermost (closest to the chip center) one of the p-type regions 31 is disposed adjacent to the p⁺⁺-type extended contact portion 15a and is closer to the chip end than is the p⁺⁺-type extended contact portion 15a.

The p⁻-type regions 32 are disposed apart from one another, concentrically surrounding the periphery of the active region 1, in a plan view of the device. The p⁻-type regions 32 are disposed in descending order of width (width in the direction of the normal) in a direction from the chip center to the chip end, and an interval between any one of the p-type regions 32 and an adjacent one of the p⁻-type regions 32 closer to the chip end is wider than an interval between said any one of the p-type regions 32 and an adjacent one of the p-type regions 32 closer to the chip center. The width of an outermost (closest to the chip end) one of the p⁻-type regions 32 may be wider than the width of an adjacent one of the p-type regions 32 closer to the chip center. An innermost (closest to the chip center) one of the p⁻-type regions 32 is disposed between all the p-type regions 31 that are adjacent to each other, is adjacent to the p-type regions 31 on both sides thereof in the direction of the normal, and borders corner portions of bottoms of all the p-type regions 31.

A center-side end (end facing the chip center) of the innermost one of the p-type regions 32 may be at a same position as a center-side end (end facing the chip center) of the innermost one of the p-type regions 31 or may be closer to the chip end than is the center-side end of the innermost one of the p-type regions 31. The innermost one of the p⁻-type regions 32 extends closer to the chip end than is an outermost one (closest to the chip end) of the p-type regions 31. The p⁻-type regions 32 other than the innermost one of the p⁻-type regions 32 are disposed closer to the chip end than are the p-type regions 31. The n⁻-type drift region 12 extends between all the p-type regions 32 that are adjacent to each other; the n⁻-type drift region 12 reaches the front surface of the semiconductor substrate 40 and is adjacent to the p-type regions 32 on both sides thereof in the direction of the normal.

Further, between the front surface of the semiconductor substrate 40 and the n⁻-type drift region 12, an n⁺-type channel stopper region 33 is selectively provided closer to the chip end than is the voltage withstanding structure 30. The n⁺-type channel stopper region 33 is a diffused region formed by ion implantation in surface regions of the n⁻-type silicon carbide layer 42. The n⁺-type channel stopper region 33 is provided apart from the voltage withstanding structure 30 in the direction of the normal, is closer to the chip end than is the voltage withstanding structure 30, and surrounds a periphery of the voltage withstanding structure 30, in a plan view of the device. The n⁺-type channel stopper region 33 is in contact with the interlayer insulating film 19 on the front surface of the semiconductor substrate 40.

The n⁺-type channel stopper region 33 is exposed at the side surface 46 of the semiconductor device. Between the n⁺-type channel stopper region 33 and the voltage withstanding structure 30 (the outermost one of the p-type regions 32), is the n⁻-type drift region 12. The n⁺-type channel stopper region 33 has a floating potential. A portion of the front surface of the semiconductor substrate 40 in the edge termination region 2 is free of a field plate (FP) and a channel stopper electrode. Instead of the n⁺-type channel stopper region 33, a p⁺-type channel stopper region may be provided.

FIG. 4 is a cross-sectional view depicting the structure of the active region of the semiconductor device according to the embodiment. The silicon carbide semiconductor device 10 depicted in FIG. 4 is a vertical MOSFET with a trench gate structure, the silicon carbide semiconductor device 10 having the voltage withstanding structure 30 in the edge termination region 2 of the semiconductor substrate (semiconductor chip) 40 containing silicon carbide (SIC).

The trench gate structure is provided in the center portion 1a of the active region 1. The trench gate structure is configured by the p-type base region 13, the n⁺-type source regions 14, the p⁺⁺-type contact regions 15, the trenches 16, gate insulating films 17, and gate electrodes 18. The p-type base region 13, the n⁺-type source regions 14, and the p⁺⁺-type contact regions 15 are diffused regions formed by ion implantation in the n⁻-type silicon carbide layer 42. In the center portion 1a of the active region 1, the p-type base region 13 is provided in an entire area between the front surface of the semiconductor substrate 40 and the n⁻-type drift region 12; the p-type base region 13 extends toward the chip end and terminates in the outer peripheral portion 1b of the active region 1.

The n⁺-type source regions 14 and the p⁺⁺-type contact regions 15 are each selectively provided between the front surface of the semiconductor substrate 40 and the p-type base region 13 and each has a bottom (lower surface: back-surface end facing the semiconductor substrate 40) in contact with the p-type base region 13. The n⁺-type source regions 14 are provided in contact with the p⁺⁺-type contact regions 15 of the center portion 1a of the active region 1, only in the center portion 1a of the active region 1. The n⁺-type source regions 14 and the p⁺⁺-type contact regions 15 each have an upper surface (end facing the front surface of the semiconductor substrate 40) in ohmic contact with ohmic electrodes 43.

Between the n⁻-type drift region 12 and the p-type base region 13, an n⁻-type current spreading region 20 and the p⁺-type regions 21, 22 are each selectively provided at deep positions closer to the n⁺-type drain region 11 (back surface of the semiconductor substrate 40) than are bottoms of the trenches 16. The n⁻-type current spreading region 20 and the p⁺-type regions 21, 22 are diffused regions formed by ion implantation in the n⁻-type silicon carbide layer 42. The n⁻-type current spreading region 20 may reach deep positions closer to the n⁺-type drain region 11 than are the p⁺-type regions 21, 22.

The n⁻-type current spreading region 20 is a so-called current spreading layer (CSL) that reduces carrier spreading resistance. The n⁻-type current spreading region 20 is provided between and in contact with the p⁺-type regions 21, 22 that are adjacent to one another; the n⁻-type current spreading region 20 extends in a direction parallel to the front surface of the semiconductor substrate 40, reaches the trenches 16, and is in contact with the gate insulating films 17. The n⁻-type current spreading region 20 has an upper surface in contact with the p-type base region 13 and a lower surface in contact with the n⁻-type drift region 12.

The n⁻-type current spreading region 20 may be omitted. In an instance in which the n⁻-type current spreading region 20 is omitted, instead of the n⁻-type current spreading region 20, the n⁻-type drift region 12 reaches the p-type base region 13, is in contact with the p-type base region 13 and the p⁺-type regions 21, 22, extends in a direction parallel to the front surface of the semiconductor substrate 40 and reaches the trenches 16, and is in contact with the gate insulating films 17.

The p⁺-type regions 21, 22 are fixed to a potential of the later-described source electrode 44, deplete (or cause the n⁻-type current spreading region 20 to deplete, or both) when the MOSFET (the silicon carbide semiconductor device 10) is off, and have a function of mitigating electric field applied to the gate insulating films 17. The p⁺-type regions 21 are provided apart from the p-type base region 13 and face the bottoms of the trenches 16 in the depth direction. The p⁺-type regions 21 are partially connected to the p⁺-type regions 22 by non-depicted portions and are thereby electrically connected to the source electrode 44.

The p⁺-type regions 21 may be in contact with the gate insulating films 17 at the bottoms of the trenches 16 or may be apart from the bottoms of the trenches 16. A width of each of the p⁺-type regions 21 is a same as a width of each of the trenches 16 or is wider than the width of each of the trenches 16. When the width of each of the p⁺-type regions 21 is wider than the width of each of the trenches 16, the p⁺-type regions 21 also face, in the depth direction, corner portions (boundary between the bottom and sidewalls) of the bottoms of the trenches 16. As a result, an effect of mitigating electric field near the bottoms of the trenches 16 by the p⁺-type regions 21 is further enhanced.

The p⁺-type regions 22 are provided between the trenches 16 that are adjacent to each other, the p⁺-type regions 22 are apart from the p⁺-type regions 21 and the trenches 16. The p⁺-type regions 22 each have an upper surface in contact with the p-type base region 13; the p⁺-type regions 22 are electrically connected to the source electrode 44 via the p-type base region 13. The p⁺-type regions 22 are each formed by an upper portion (portion facing the n⁺-type source regions 14) 24 formed in the n⁻-type silicon carbide layer 42 and a lower portion (portion facing the n⁺-type drain region 11) 23 formed in the n⁻-type silicon carbide layer 42 and adjacent to the upper portion 24 in the depth direction.

The trenches 16 penetrate through the n⁺-type source regions 14 and the p-type base region 13 in the depth direction and terminate in the n⁻-type current spreading region 20 (in an instance in which the n⁻-type current spreading region 20 is omitted, the n⁻-type drift region 12). The trenches 16 may terminate in the p⁺-type regions 21. The trenches 16, for example, extend in a striped pattern in a direction parallel to the front surface of the semiconductor substrate 40 and reach the outer peripheral portion 1b of the active region 1. In the trenches 16, the gate electrodes 18 are provided via the gate insulating films 17, respectively.

The interlayer insulating film 19 is provided in an entire area of the front surface of the semiconductor substrate 40 and covers the gate electrodes 18. The ohmic electrodes (first electrodes) 43 are provided on portions of the front surface of the semiconductor substrate 40, the portions exposed in contact holes of the interlayer insulating film 19. The ohmic electrodes 43, via the contact holes of the interlayer insulating film 19, are in ohmic contact with the n⁺-type source regions 14 and the p⁺⁺-type contact regions 15 (in an instance in which the p⁺⁺-type contact regions 15 are omitted, the p-type base region 13) at the front surface of the semiconductor substrate 40. The ohmic electrodes 43, for example, are constituted by a nickel silicide (NixSiy, where x and y are integers) film.

The source electrode (first electrode) 44 is provided on the interlayer insulating film 19 so as to be embedded in contact holes of the interlayer insulating film 19. The source electrode 44 is provided in substantially an entire area of the center portion 1a of the active region 1 and is electrically connected to the n⁺-type source regions 14, the p⁺⁺-type contact regions 15, the p-type base region 13, and the p⁺-type regions 21, 22 via the ohmic electrodes 43.

A barrier metal 38 that prevents diffusion of metal atoms to the gate electrodes 18 may be provided on the ohmic electrodes 43 and the interlayer insulating film 19. The barrier metal 38, for example, contains titanium (Ti) or titanium nitride (TiN). The barrier metal 38 may have a two-layer structure of titanium (Ti) and titanium nitride (TiN). In this instance, the source electrode 44 is provided on the barrier metal 38.

Further, to prevent diffusion of ions into the semiconductor device and to protect and insulate the semiconductor device, the polyimide film 34 is formed on the interlayer insulating film 19 in the edge termination region 2 and on the source electrode 44 in the active region 1.

An opening (not depicted) is provided in the polyimide film 34 and a portion of the source electrode 44 exposed in the opening of the polyimide film 34 constitutes a source pad. FIG. 3 depicts a portion free of the opening.

A drain electrode (second electrode) 45 is provided in an entire area of the back surface (back surface of the n⁺-type starting substrate 41) of the semiconductor substrate 40, is in ohmic contact with the n⁺-type drain region 11 (the n⁺-type starting substrate 41), and is electrically connected to the n⁺-type drain region 11.

Next, a method of manufacturing the semiconductor device according to the embodiment is described. First, similar to a method of manufacturing a semiconductor device by a conventional technique, surface structures are formed on the semiconductor substrate 40. In the semiconductor substrate 40, the MOS structure of the active region 1 and the voltage withstanding structure 30 of the edge termination region 2 and the like are formed. Next, the interlayer insulating film 19 is formed at the front surface of the semiconductor substrate 40. Next, in the center portion 1a of the active region 1, an opening is formed in the interlayer insulating film 19 and in the active region 1, the barrier metal 38 and the source electrode 44 are formed.

Next, the polyimide film 34 is selectively formed on the source electrode 44 of the center portion 1a of the active region 1 and on the interlayer insulating film 19 in the outer peripheral portion 1b of the active region 1 and the edge termination region 2. The polyimide film 34 is formed at least 0.66 d apart from the end T of the semiconductor device. In an instance in which the side surface 46 of the semiconductor device is θ degrees from vertical after dicing due to the setting of dicing equipment, the polyimide film 34 may be formed at least d tan θ+0.66 d from the end T or the polyimide film 34 may be formed at least D tan θ+0.66 d from the end T of the semiconductor device.

Next, nickel or titanium (Ti) is deposited in an entire area of the back surface of the semiconductor substrate 40 and thereafter, annealing is performed, thereby forming the drain electrode 45. Next, in the center portion 1a of the active region 1, the polyimide film 34 is selectively removed. A portion exposed in an opening of the polyimide film 34 constitutes the source pad. Next, the semiconductor substrate is diced (cut) into individual chips. Thus, the semiconductor device according to the embodiment is completed.

As described above, according to the semiconductor device of the embodiment, the polyimide film is at least 0.66 d apart from the end of the semiconductor device. As a result, even when blue light is transmitted through the interlayer insulating film and emitted from the surface of the semiconductor device, the blue light is not absorbed by the polyimide film. Thus, decreases in the reliability of the semiconductor device may be prevented without changes in the composition (structure) of the polyimide film due to the blue light and without degradation of the adhesion between the polyimide film and the interlayer insulating film.

In the foregoing, the present disclosure may be variously modified within a range not departing from the spirit of the disclosure and in the embodiments described above, for example, dimensions, doping concentrations of regions, etc. may be variously set according to necessary specifications. Further, in the embodiments described above, a semiconductor other than silicon carbide (SIC) such as gallium nitride (GaN) may be applied as a semiconductor. Further, in the embodiments described above, while a MOSFET is described as an example, application is further possible to a semiconductor device having therein pn junctions such as, for example, an IGBT, a pn diode, and a Schottky barrier diode (SBD) employing a junction barrier Schottky (JBS) structure.

According to the disclosure above, even when blue light is transmitted through the interlayer insulating film and emitted from the surface of the semiconductor device, the blue light is not absorbed by the polyimide film. Thus, decreases in the reliability of the semiconductor device may be prevented without changes in the composition (structure) of the polyimide film due to the blue light and without degradation of the adhesion between the polyimide film and the interlayer insulating film.

The semiconductor device according to the disclosure achieves an effect in that degradation of polyimide due to blue light is prevented and decreases in reliability may be prevented.

As described, the semiconductor device according to the disclosure is useful for power semiconductor devices used in power converting equipment of inverters and the like, power source devices of various types of industrial machines and the like, and igniters of automobiles, etc.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having an active region and a termination region surrounding a periphery of the active region, the semiconductor device comprising:
in the termination region,
a semiconductor substrate of a first conductivity type;
a first semiconductor region of the first conductivity type, provided on a surface of the semiconductor substrate, the first semiconductor region having a thickness “d”;
an insulating film provided on a surface of the first semiconductor region; and
a polyimide film selectively provided on a surface of the insulating film, wherein
the polyimide film is provided at least a distance of 0.66 d from an outer periphery end of the semiconductor device.

2. The semiconductor device according to claim 1, wherein
the semiconductor device has a side surface at the outer periphery end thereof that is inclined at θ degrees inward from vertical, and
the polyimide film is provided at least a distance of 0.66 d+d tan θ from the outer periphery end of the semiconductor device.

3. The semiconductor device according to claim 1, wherein
the semiconductor device has a side surface at the outer periphery end thereof that is inclined at θ degrees inward from vertical,
the semiconductor substrate has a thickness “D”, and
the polyimide film is provided at least a distance of 0.66 d+D tan θ from the outer periphery end of the semiconductor device.
